(19) United States
(12) Patent Application Publication
(10) Pub. No.: US 2011/0273203 A1
(43) Pub. Date: Nov. 10, 2011

(54) METHOD FOR THE TESTING OF CIRCUIT BOARDS

(75) Inventors: Victor Romanov, Wertheim (DE); Gilbert Volpert, Wertheim/Reicholzheim (DE); Martin Faulhaber, Konigheim (DE)

(73) Assignee: DTG International GMBH, Zurich (CH)

(21) Appl. No.: 13/143,697

(22) PCT Filed: Jan. 13, 2010
(86) PCT No.: PCT/EP10/50361

§ 371 Date: Jul. 7, 2011

(30) Foreign Application Priority Data
Jan. 14, 2009 (DE) 10 2009 004 555.4

(51) Int. Cl. G01R 31/28

(52) U.S. Cl. 324/763.01

(57) ABSTRACT

The invention relates to a method for the testing of circuit boards using a testing apparatus which has a test set-up for contacting the circuit board test points of a circuit board to be tested. The test set-up has test contact elements in a predetermined regular grid. The method involves the following steps:
a) the test set-up is pressed on to the circuit board to be tested in a first testing position relative to the circuit board to be tested, so that several circuit board test points are in contact with at least one test contact element
b) measurement of several conductor paths for breaks and/or short-circuits by means of continuity measurements
c) movement of the test set-up relative to the circuit board to be tested into another testing position in which at least one circuit board test point of a conductor path is in contact with at least one test contact element, which has not previously been measured fully for breaks and/or short-circuits
d) measurement of further conductor paths for breaks and/or short-circuits by means of continuity measurements
e) repetition of steps c) and d) until at least the majority of conductor paths of the circuit board to be tested have been measured, wherein
   a test set-up is used which has test contact elements arranged with a density of at least 100 contact points per square centimetre.

The present invention relates to a method for the testing of circuit boards using a testing apparatus; in particular the present invention relates to a method for the testing of non-componented circuit boards for breaks and short-circuits by means of continuity measurements.

The term “continuity measurements” describes measurements in which an electrical resistance between two contact points of one or more conductor paths is measured by contacting the two contact points and applying a measuring current or measuring voltage, and then measuring the resulting voltage or the resulting current. The contact points of a conductor path are subsequently described as circuit board test points. Breaks in a conductor path are detected by contacting the conductor path at two circuit board test points and detecting a predetermined minimum resistance. Short-circuits between two adjacent conductor paths are detected by contacting in each case one circuit board test point of one of the two conductor paths and measuring a resistance which is below a predetermined threshold value.

Testing apparatus for the testing of circuit boards may be divided into two basic groups: the group of the finger testers (flying probe testers) and the group of the parallel testers. Parallel testers are a kind of testing apparatus which, by means of an adapter, is able to contact simultaneously all or at least most of the contact points of a circuit board to be tested. Finger testers are testing apparatus for the testing of non-componented or componented circuit boards in which the individual contact points are scanned sequentially by two or more test fingers.

A finger tester is described in EP 0 468 153 A1, and a method for the testing of circuit boards by means of a finger tester is described in EP 0 853 242 A1.

Typical parallel testers are known from U.S. Pat. No. 3,564,408 and U.S. Pat. No. 4,417,204, from DE 32 40 916 C2, from DE 33 40 180 C1, from German utility model patent DE 88 06 064 U1, from EP 0 875 767 A2, from WO 02/31516 and EP 1 322 967 B1, and from EP 1 083 434 A2 and U.S. Pat. No. 6,445,173 B1.

DE 88 06 064 U1 discloses a testing apparatus in which the contact elements of a parallel tester are formed of rigid pins which are tilted at an angle when contacting a circuit board in which the contact points are arranged outside grids. In the case of circuit boards in which all contact points are arranged in a predetermined regular grid, it is of course not necessary for the rigid pins to be titled at an angle.

A number of attempts have also been made to remove the distinction between parallel testers and finger testers, and to create a type of universal parallel tester, which would involve overcoming the disadvantage of parallel testers that a separate adapter must be provided for each type of circuit board, while retaining their advantage of a high testing rate.

WO 97/23784 discloses a testing apparatus which has on each side of the test specimen to be tested at least two co-planar needle boards, movable relative to one another. These needle boards are provided with several test needles, each of which may be used to contact one contact point of a conductor path to be tested. The two needle boards may be moved relative to the circuit board in such a way that specific contact points of a conductor path may be contacted simultaneously, while several conductor paths may also be contacted simultaneously through the several contact points of the needle boards. The contact needles of each needle board may be actuated individually, so that only selected contact needles of a contact board are in contact with the respective circuit board to be tested.

WO 99/23496 discloses a testing apparatus for the testing of circuit boards which has a multiplicity of contact elements, arranged on a support element and movable selectively on the support element in the direction of a circuit board to be tested. The individual contact elements may therefore be driven individually. The support elements are movable in a plane parallel to the circuit board to be tested, so that each contact point of the circuit board to be tested may be contacted by at least one contact element.

While the two testing apparatuses described above admittedly do combine the advantages of the parallel tester and the finger tester, they have not proved successful in practice, since the individual control of the separate contact elements is very laborious. An apparatus of this kind is on the one hand expensive and on the other hand prone to faults and therefore maintenance-intensive. In addition, because they are individually controlled, the separate contact elements are arranged with relatively large clearance from one another, so that such apparatus is of only limited use for current circuit boards.

Known from DE 40 12 839 B4 is a method of testing circuit boards which uses a conductor structure with scanning points arranged in such a close grid that an image of the conductor structures on the surface of the test specimen is obtained.

EP 1 022 572 B1 and EP 1 312 930 B1 disclose testing apparatus in which contact brushes move over the surfaces of circuit boards, thereby creating electrical contacts with the individual contact points. In the course of this, electrical values are measured and compared with pre-defined values. This allows the elimination of certain contact points for subsequent detailed electrical testing of the circuit board to be tested.

EP 0 831 332 A1, U.S. Pat. No. 4,820,975, EP 0 859 239 A2, EP 0 994 359 A2, DE 44 06 538 A1, EP 0 874 243 A2, WO 95/32432, DE 43 42 654 A1, JP 63124969, JP 4038480 and DE 43 02 509 A1 disclose devices and methods in which the circuit board to be tested is aligned in a parallel tester relative to the adapter, wherein in each case a relative movement is made between the circuit board to be tested and the adapter. The adjusting devices for executing this adjusting be may be arranged completely within the adapter body (EP 0 831 332 A1) or also outside the adapter body, so that the whole adapter is moved (U.S. Pat. No. 4,820,975). It is also possible to adjust subsets of the contact elements of the adapter independently of one another (DE 44 06 538 A1). Reference is made in full to all these documents which describe a device and/or a method for executing a relative movement between a circuit board to be tested and an adapter.

Described in DE 199 57 286 A1 is a method in which different areas of a circuit board are aligned individually relative to an adapter of a parallel tester. In this case an adapter specific to the circuit board is used, and the contact points of the adapter are configured in the grid of the circuit board test points of the circuit board to be tested.

DE 143 728 A1 discloses a method in which a circuit board is firstly tested using a parallel tester. Circuit board test points which cannot be contacted are measured afterwards using a device independent of the parallel tester. This independent device is generally a finger tester.

The present invention is based on the problem of creating a method and an apparatus for the testing of circuit boards in which no specific adaptation of the apparatus to the respective type of circuit board to be tested, for example by means of an adapter, is required, and on the other hand rapid measurement of at least the majority of the conductor paths for breaks and short-circuits is possible.

The problem is solved by a method with the features of claim 1 and an apparatus with the features of claim 8. Advantageous developments are set out in the respective dependent claims.

In the method according to the invention for the testing of circuit boards, the testing apparatus used has a test set-up for contacting the circuit board test points of a circuit board to be tested, in which the test set-up has test contact elements in a predetermined regular grid. The method involves the following steps:

a) the test set-up is pressed on to the circuit board to be tested in a first testing position relative to the circuit board to be tested, so that several circuit board test points are in contact with at least one test contact element
b) measurement of several conductor paths for breaks and/or short-circuits by means of continuity measurements
c) movement of the test set-up relative to the circuit board to be tested into another testing position in which at least one circuit board test point of a conductor path is in contact with at least one test contact element, which has not previously been measured fully for breaks and/or short-circuits
d) measurement of further conductor paths for breaks and/or short-circuits by means of continuity measurements
e) repetition of steps c) and d) until at least the majority of conductor paths of the circuit board to be tested have been measured, wherein a test set-up is used which has test contact elements arranged with a density of at least 100 contact points per square centimetre.

Surprisingly it has been found that, by using a test set-up with a density of contact points of at least 100 contact points per cm², it is possible to test completely or almost completely circuit boards in current use with just a few movements of the test set-up relative to the circuit board to be tested. Due to the high density of contact points, large circuit board test points of the circuit board to be tested are contacted several times, so that they are as a rule always contacted irrespective of the position of the contact configuration relative to the circuit board to be tested.

Smaller circuit board test points are on the other hand contacted only in specific testing positions of the test set-up, for which reason the movement of the test set-up relative to the circuit board to be tested is necessary in order to obtain complete or at least almost complete measurement of the circuit board to be tested.

The test set-up according to the invention with test contact elements arranged in a regular grid is used for different types of circuit board. With it, circuit board test points located outside the grid are contacted, as is usual with current circuit boards. It is therefore not necessary to create a separate test set-up for each type of circuit board. This test set-up may therefore also be described as a “universal adapter”.

The method according to the invention is especially well suited to the testing of short-circuits between adjacent conductor paths since, for the majority of circuit boards, these may be measured completely with just a few movements.

Due to the high density of contact elements, the maximum movement distance required for the test set-up relative to the circuit board is very small, and limited to the distance between two adjacent test contact elements of the test set-up. It is therefore sufficient for the test set-up to be capable of traversing, relative to the circuit board to be tested, in the plane parallel to the circuit board to be tested in two orthogonal directions, in each case by +/−half the distance between two adjacent test contact elements.

The individual test contact elements are preferably fixed rigidly to the test set-up, which means that the test set-up may have a simple and cost-effective design, with contact elements at the required density. Rigid fixing should be understood as meaning a fixing of the test contact element so that an individual test contact element is not movable relative to the test set-up as a whole. However, this does not mean that the individual test contact elements must be made integral with the test set-up. A rigid test set-up may for example also have as test contact elements separately formed test needles, fixed in their position on a basic grid by means of leader boards.

Since the test contact elements are arranged in a regular grid then, where the test contact elements are in the form of test needles, the test needles may all be aligned parallel to one another. Conventional parallel testers have adapters with test needles which are usually inclined at an angle. The parallel arrangement of the test needles is more advantageous than the inclined position, since all test needles are arranged in one plane with their ends facing the circuit board to be tested, so that they contact the circuit board to be tested simultaneously and only relatively low contact pressure is required to ensure that all test needles are in contact with the circuit board to be tested. When the test needles are inclined, which generally involves varying degrees of inclination, then the less inclined test needles must be compressed more, so that the more sharply inclined test needles also make contact with the circuit board to be tested. As a result of this, very much greater contact forces are generated. The inclined position also reduces the distance between adjacent test needles. Since the test needles are arranged parallel to one another it is also possible, with such a high density of test needles, to use needles with a sprung section, e.g. in the form of a coil spring.

For the situation in which not all conductor paths can be measured completely, the circuit board may undergo a further measurement with a finger tester. This will require the contacting of only a few circuit board test points, so that this measurement may be conducted very quickly. The whole measurement comprising the step-by-step parallel scanning of the circuit board to be tested using the test set-up, with subsequent testing by the finger tester, is very much faster than complete scanning and measurement of the circuit board to be tested in a finger tester.

With the method according to the invention, the universal applicability of the testing apparatus, as known from the finger tester, is therefore combined with a throughput which is roughly as fast as that of a parallel tester.

The invention is explained in detail below by examples and with the aid of the drawings, which show in:

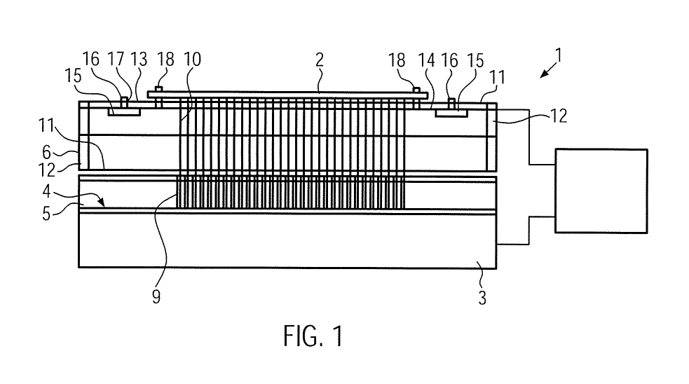

FIG. 1 the design of a testing apparatus according to the invention in schematic form

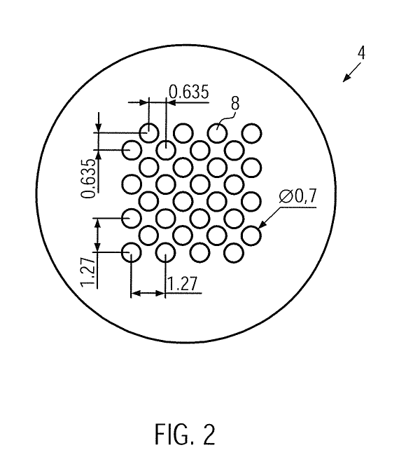

FIG. 2 a detail of the arrangement of the test contact elements of the testing apparatus of FIG. 1

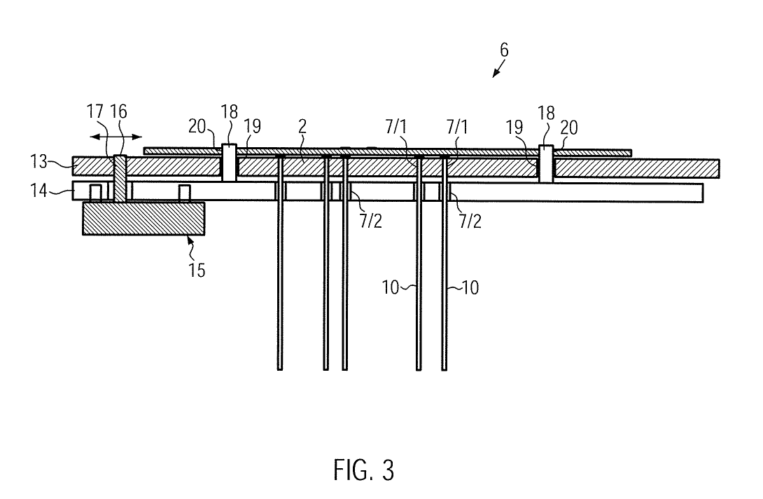

FIG. 3 an area of the contacting unit of the testing apparatus shown in FIG. 1, in schematic form

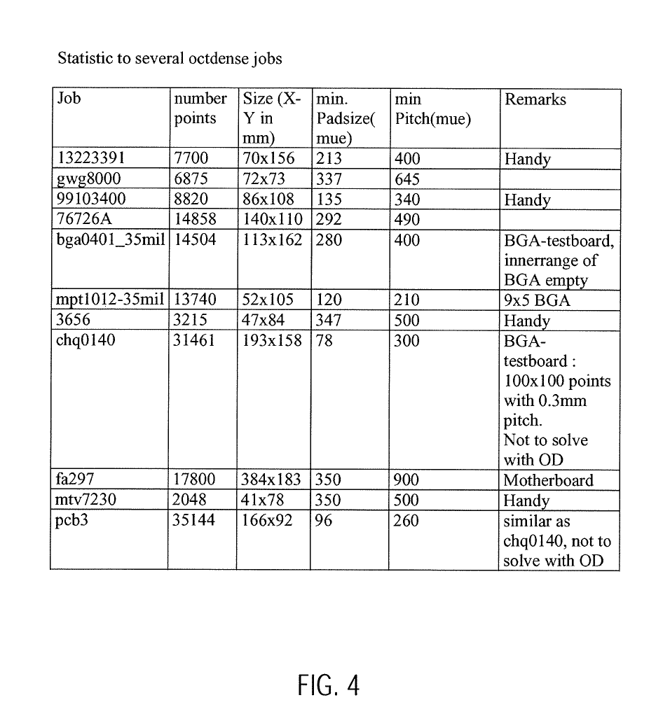

FIG. 4 a table of data from different circuit boards to be tested

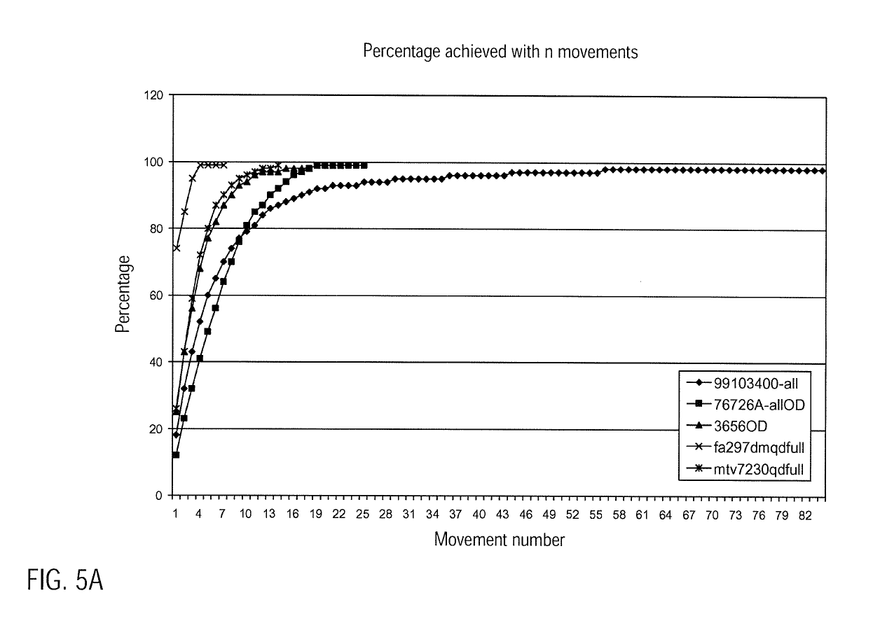

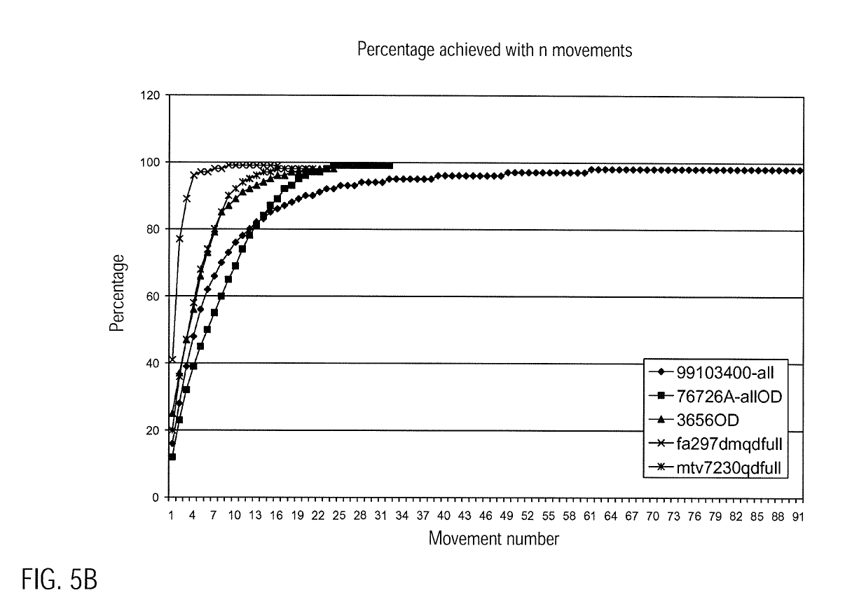

FIGS. 5A, 5B the relationship between the number of circuit board test points covered and the number of measuring operations and/or movements for different test contact element densities, each in a diagram

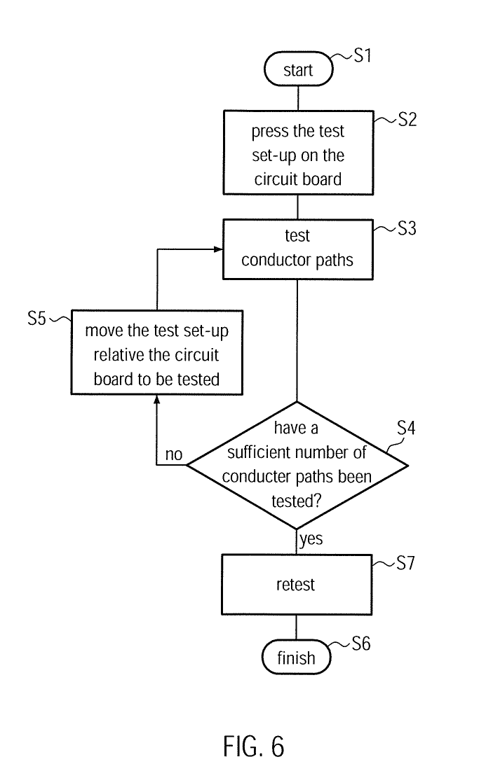

FIG. 6 a flow chart showing the method according to the invention

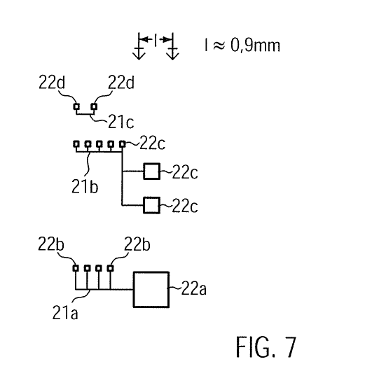

FIG. 7 an enlarged view of circuit board conductor paths to be tested, and

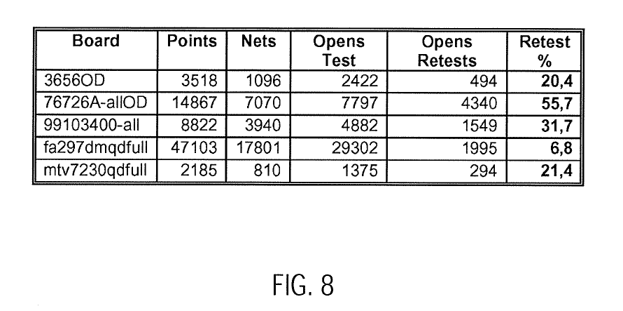

FIG. 8 a table showing the proportion of continuity measurements for breaks (opens) which could not be performed on certain circuit boards, for a predetermined number of movements.

FIG. 1 shows in schematic form the design of a testing apparatus 1 according to the invention for testing one side of circuit boards 2. This testing apparatus has a body 3 which holds part of the evaluation electronics and has a basic grid 4 formed on its surface. A detail of the basic grid is shown in FIG. 2. Modules for the forming of this basic grid are disclosed in German patent application DE 10 2006 059 429. Reference to this patent application is hereby made in full.

Mounted on the body 3 is a full grid cassette 5, and mounted on the full grid cassette 5 is a contacting unit 6, on which a circuit board 2 to be tested is placed.

The basic grid 4 has contact points 8, which are circular in form. The grid in which the contact points 8 are arranged is comprised of two square grids interlaced with one another. In the square grids, the contact points 8 are each spaced 1.27 mm apart, with a contact point 8 located at each corner point of a square. In the centre between four contact points 8 of a grid located in the corners of a square, there is in each case a contact point of the other square grid. These two grids are thus offset relative to one another by half the distance between two adjacent contact points of a square grid. This half-distance amounts to 0.635 mm (FIG. 2). The density of the contact points of this grid comes to approx. 124 contact points per cm². This grid may also be described as a square grid, in which the side edges of the square each run at an angle of 45° to the verticals and horizontals in FIG. 2. In this illustration, the distance between two adjacent contact points is 0.898 mm.

The full grid cassette 5 has spring contact pins 9. The spring contact pins 9 are arranged in the raster of the basic grid 4, so that a spring contact pin 9 is assigned to each contact point 8 of the basic grid 4. The spring contact pins 9 are mounted parallel to one another in the full grid cassette 5.

The design of the contacting unit 6 is similar to that of conventional adapters and has test needles 10, each of which leads upwards from a spring contact pin 9 of the full grid cassette 5 towards the circuit board 2 to be tested, which they contact. Conventional adapters are designed so that, through the inclined position of the test needles, they image the grid of the basic grid and the full grid cassette respectively on the arrangement of the circuit board test points of the circuit board to be tested. The arrangement of the circuit board test points of the circuit board to be tested is thus adapted to the basic grid. Such adaptation of two arrangements of contact elements is not effected by the contacting unit 6 according to the invention. The test needles 10 of the contacting unit 6 are, just like the spring contact pins 9 of the full grid cassette 5, arranged in a regular grid, namely in the grid of the basic grid 4. They are all aligned parallel to one another. This contacting unit 6 is therefore not an adapter. When a circuit board 2 to be tested is placed on the contacting unit 6, not all circuit board test points of the circuit board to be tested are contacted simultaneously.

The contacting unit 6 has several leader boards 11 which are provided with holes 7/1, each arranged in the grid of the basic grid. The test needles 10 extend through these holes. The leader boards 11 are held on the edge with clearance by means of sprung columns 12. One of the leader boards 11, preferably that which borders the contacting unit 6 on the circuit board side, is in the form of a needle guide board 13. Mounted adjacent to the needle guide board 13 is a positioning board 14, which has holes 7/2 with a larger diameter than the holes of the other leader boards 11, so that the test needles 10 are located in the positioning board 14 with considerable play. Fixed to the positioning board 14 is an adjusting device or traversing device 15 which has an upwards projecting adjusting pin 16, which may be moved relative to the positioning board 14 a predetermined distance of for example 0.9 mm in one direction by means of an actuator in the adjusting device 15. This adjusting pin 16 engages positively in a positioning hole 17 of the needle guide board 13. By this means, the positioning board 14 is designed so as to be capable of movement relative to the needle guide board 13. The contacting unit 6 has several such adjusting devices 15, so that it is able to move the positioning board 14 relative to the needle guide board 13 in two orthogonal directions (X-direction and Y-direction) independently of one another.

Fixed to the positioning board 14 are circuit board locating pins 18 which extend through corresponding holes 19 in the needle guide board 13 towards the circuit board 2 and engage positively in positioning holes 20 in the circuit board 2. The holes 19 in the needle guide board 13 are distinctly larger than the diameter of the circuit board locating pin 18, so that the relative movement between the needle guide board 13 and the positioning board 14 is not restricted by this factor. Since the circuit board locating pins 18 engage positively in the circuit board 2, any movement of the positioning board 14 is transmitted directly to the circuit board 2.

The positioning board 14 and the circuit board locating pins 18 thus form a positioning device for the circuit board 2. The relative movement between the needle guide board 13 and the positioning board 14 is therefore also a relative movement between the needle guide board 13 and the circuit board 2.

Preferably two circuit board locating pins 18 are provided, so that the circuit board 2 is distinctly positioned relative to the positioning board 14.

The actuator of the adjusting device or movement device 15 is a piezoelectric actuator, as known from EP 0 831 332 A1. Reference is made to this document in respect of the piezoelectric actuator. This piezoelectric actuator has two sets of piezoelectric element rods, arrange orthogonally to one another. The piezoelectric element rods are acted on by a voltage so that they extend or contract. The voltages applied to a pair of piezoelectric element rods are opposite in polarity so that the piezoelectric element rods, due to the opposing contraction and extension in length, deflect and execute a pivoting movement. Since two pairs of piezoelectric element rods are provided, pivoting movements may be made in two orthogonal directions (X-direction and Y-direction), and the needle guide board 13 may thus be shifted in both the X-direction and the Y-direction in the plane parallel to the circuit board 2. The maximum movement distance amounts to +/−0.45 mm.

This movement distance is distinctly greater than that of known devices for automatic positioning and fine adjustment of circuit boards on a parallel tester. The adjusting device 15 is therefore provided with greater dimensions than is the case with conventional adjusting devices.

Instead of a piezoelectric actuator, a step motor with a reduction gear may also be provided, to drive a suitable adjusting spindle. Such an adjusting unit may be provided inside the contacting unit 6 to move the needle guide board 13, or outside the contacting unit 6 to move the unit comprising the body 3, the full grid cassette 5 and the contacting unit 6. It is also possible to move the circuit board 2 directly by means of the adjusting unit of the circuit board 2.

Another actuator may be in the form of a motor with a reduction gear driving an eccentric. With this, the movement distances may be adjusted in a simple manner. The motor may be a step motor or a servomotor with feedback, in which the movement distance is determined by means of a movement sensor and fed back accordingly to the drive of the motor.

The testing apparatus has been described above with the aid of a device for testing one side of a circuit board. Nowadays, however, devices for testing both sides of circuit boards are usual. For testing both sides of a circuit board, the unit comprising the body 3, the full grid cassette 5 and the contacting unit 6 is provided twice, namely once below and once above the circuit board to be tested, in each case with the contacting unit 6 facing towards the circuit board. These two units are arranged between a press, so that the contacting units 6 are pressed against the circuit board from top and bottom.

In a two-sided testing apparatus, adjusting devices may be provided for positioning the needle guide boards of both contacting units. It is however also possible to provide adjusting devices only for positioning a needle guide board, and a further adjusting unit for positioning the circuit board. It is expedient to arrange the adjusting devices in such a way that both contacting units may be moved independently of one another relative to the circuit board to be tested.

The method of testing non-componented circuit boards is explained below with the aid of FIG. 6.

The method begins with step S1.

In step S2, the test set-up is pressed against the circuit board 2 to be tested. In the apparatus described above, the contacting unit 6 forms the test set-up. In the case of a device for testing both sides of a circuit board, the two contacting units 6 represent the test set-up for testing the top and bottom of the circuit board to be tested. Such a test set-up is therefore distinguished by test contact elements arranged in the regular grid and movable relative to the circuit board to be tested. In the device described above, the test needles 10 form the test contact elements.

In step S3, conductor paths and conductor path sections in which circuit board test points located at the respective ends of the conductor paths and conductor path sections are contacted by a test contact element, are tested for breaks by means of a continuity measurement. Adjacent conductor paths, in which in each case one circuit board test point is contacted by a test contact element, are tested for short-circuits by means of a continuity measurement.

In step S4 a check is made as to whether a sufficient number of conductor paths have been tested for breaks and short-circuits.

If this is not the case, then the process sequence moves on to step S5, in which the test set-up is shifted relative to the circuit board to be tested. If the circuit board is being tested on both sides, then preferably one part of the test set-up which contacts one side of the circuit board is moved independently of the part of the test set-up which contacts the other side of the circuit board. The movement is made in such a way that conductor paths and conductor path sections not yet tested are contacted by test contact elements at their circuit board test points formed at the end sections, so that these further conductor paths and conductor path sections may be tested for breaks and/or short-circuits. The measurement takes place again in step S3.

This is followed by a further check to ascertain whether or not a sufficient number of conductor paths have been tested (S4).

It has been found that a grid of at least 100 test contact elements per cm² and in particular the grid shown in FIG. 2 is sufficient to enable all circuit board test points of all conductor paths to be contacted, so that the circuit board test points of a conductor path may be contacted simultaneously with a specific test set-up, and the conductor path or the relevant conductor path section may be measured for breaks. This is based on the fact that the circuit board test points, which are normally in the form of via holes or pad fields, are often of a size which is greater than the distance between two adjacent test contact elements, so that such a circuit board test point is contacted in any testing position of the test set-up, and a further circuit board test point of this conductor path, which is in the form of a small pad field, may be contacted specifically, while the large circuit board test point is also reliably contacted at the same time.

If the circuit board being tested is one for which all conductor paths may be scanned reliably by the test set-up, then in step S4 the number determined as an adequate number of conductor paths will preferably be the same as the number of all conductor paths, so that with repeated passage through steps S3, S4 and S5 the circuit board is completely tested. The process then finishes with step S6.

In determining the respective movement distance, a distinction is made as to whether only short-circuits or breaks are to be measured.

For the measurement of short-circuits between adjacent conductor paths, these conductor paths must be contacted simultaneously. This contacting may however take place at any desired point on the conductor path. A continuity measurement is then made between the conductor paths.

For measuring breaks on conductor path sections, the conductor path sections are contacted at their end points. A continuity measurement is then made between the relevant end points or circuit board test points.

For measuring short-circuits, a check is made in a first test position to reveal which adjacent conductor paths are contacted simultaneously. These pairs of conductor paths may then be tested for short-circuits. These pairs of conductor paths are recorded as already tested pairs.

An as yet untested pair of conductor paths which may be contacted simultaneously is then selected. The relevant movement distance is calculated. Preferably the further pair of conductor paths is chosen so that the movement distance is as short as possible.

In the new test position obtained through the movement, it is determined which further pair of adjacent conductor paths may be contacted simultaneously. These pairs of conductor paths may then be tested for short-circuits, and are then recorded as already tested pairs.

The determination of a movement distance is repeated until all or at least the majority of pairs of adjacent conductor paths have been tested for short-circuits.

In measuring for breaks, testing takes place in every test position in which conductor path sections are contacted at their end points. These conductor path sections may then be tested by a continuity measurement. Conductor path sections already tested are recorded. The movement distance is determined so that, after the movement, a conductor path section not yet tested is contacted at its end points. Preferably the movement distance is kept as small as possible.

In a combined method of testing for breaks and short-circuits, in each test position both pairs of contacted adjacent conductor paths and also already contacted conductor path sections are noted. The movement distance is preferably optimised for conductor path sections, since this almost always results in complete coverage of potential short-circuits. It is however also possible to determine the movement distance alternately for conductor path sections and pairs of adjacent conductor paths.

In principle it is possible to have conductor paths which cannot be scanned completely by the grid of the test set-up, i.e. the circuit board test points of these conductor paths are so arranged that not all conductor path sections can be tested for breaks by a continuity measurement or adjacent conductor paths with their circuit board test points are so arranged that the two conductor paths cannot be contacted simultaneously by the test set-up.

FIG. 7 shows three conductor paths 21a, 21b and 21c. Conductor path 21a has as circuit board test points pad fields 22a, 22b. The pad fields 22a, 22b are square, with pad field 22a having an edge length of 1 mm and the several pad fields 22b an edge length of 0.1 mm. Since the pad fields 22b are very much smaller than the grid spacing L (0.9 mm) between two adjacent test contact elements, it is not possible to contact all pad fields 22b in pairs. This is not necessary since, to test the conductor path 21a, it is quite sufficient for one of the small pad fields 22b to be contactable at the same time as the large pad field 22a, so that the respective conductor path section running between these two pad fields may be tested for breaks. Since the pad field 22a with an edge length of 1 mm is greater than the grid dimensions of the test set-up, the test set-up may be aligned with one test contact element exactly on one of the small pad fields 22b in each case, while the size of the large pad field 22a ensures that one or more test contact elements is or are in contact with this pad field 22a. Consequently all conductor paths which have as circuit board test point at least a square pad field with the edge length of the grid dimension of the test set-up may be tested completely for breaks.

In practice, square pad fields with a minimum edge length of up to 0.05 mm are common. There are also quite frequently square pad fields with an edge length of 0.1 mm. However it has been found that conductor paths which are connected to such small pad fields are generally also connected to a larger pad field with an edge length of at least 1 mm and/or a via hole. Via holes usually have a plated ring with a width of 0.5 to 1 mm, so that the via holes are normally contacted simultaneously by several test contact elements of the test set-up, thereby also permitting contacting in pairs to all desired further circuit board test points of a conductor path connected to a via hole.

Only conductor paths provided solely with circuit board test points in the form of pad fields which are distinctly smaller than the grid dimension I of the test set-up may perhaps not be scanned completely by the test set-up. In FIG. 7, conductor path 21b represents a conductor path connected to pad fields 22c, which are square and have an edge length of 0.4 mm, and also connected to further pad fields 22d, which have an edge length of 0.1 mm. Since the pad fields 22c with their edge length of 0.4 mm are already of considerable size, generally contacting in pairs with one of the other pad fields of these conductor paths is possible. However it is not possible to rule out entirely that certain conductor path sections may not be scanned correctly.

The conductor path 21c in FIG. 7 connects two pad fields 22d with an edge length of 0.1 mm. These two pad fields are not located in the grid of the test set-up. The two pad fields 22d of this conductor path 21 can not be contacted simultaneously by the test set-up, so that the conductor path 21c cannot be tested for breaks. The number of such conductor paths which cannot be contacted correctly is generally very small. Also such conductor paths are usually very short conductor paths with only a few circuit board test points.

If a circuit board has such conductor paths, then in step S4 a threshold for the adequate number of tested conductor paths must be used which is below the number of non-testable conductor paths. According to the invention a threshold of 5% to 10% of non-testable conductor paths relative to all conductor paths may be met.

If then it is established in step S4 that an adequate number of conductor paths have been tested, but not all conductor paths have been tested, then in step S7 the non-tested conductor paths are subsequently measured using another measuring method. Preferably the circuit board is re-tested in step S7 by a finger tester. Since the conductor paths which could not be scanned correctly are generally very short and have only a few circuit board test points, the re-testing of these conductor paths using a finger tester may be carried out very quickly. Calculations have revealed that with such a test set-up (grid dimension approx. 0.9 mm) and with currently available non-componented circuit boards, around 20 to 30 movement shifts are necessary to test all conductor paths completely for breaks and short-circuits. There are few circuit boards which cannot be scanned completely. These must then be retested using a finger tester.

In re-testing, at least the pairs of conductor paths which could not be contacted to measure a potential short-circuit and/or the conductor path sections which could not be tested for breaks are re-tested. It is however also possible in re-testing to check once more the faults detected in step S3.

Since a test set-up with a density of at least 100 test contact elements per square centimetre is used, a multiplicity of circuit board test points are contacted simultaneously by several test contact elements or test needles 10. By this means it is possible to check the correct positioning of the test set-up on the circuit board, by testing at certain circuit board test points which should be contacted by at least two test contact elements, whether in each case an electrical contact has been made between these two test contact elements via the circuit board test point. If this check is performed at several circuit board test points then, if a connection between the adjacent test contact elements is made at all these circuit board test points, it may be concluded that the test set-up is in the desired position on the circuit board.

Calculations have been made to determine how many movements are required to contact all or at least nearly all conductor paths, or how many movements are necessary to contact all or at least nearly all conductor path sections at their end circuit board test points. FIG. 4 shows a table containing the data on circuit boards for which the calculation has been made.

Diagrams 5A and 5B show the percentage of scanned circuit board test points of the conductor paths relative to the number of movements and measurements. The calculations according to FIG. 5A are based on the contact layout shown in FIGS. 1 and 2. The calculations according to FIG. 5B have been based on a contact configuration with twice the density of that shown in FIGS. 1 and 2. Only with a single circuit board (type no. 09102300) was it not possible to contact all circuit board test points with a number of movements between 20 and 30. For all the other circuit boards, all circuit board test points could be contacted.

For a short-circuit test it is essentially sufficient if at least one circuit board test point per conductor path can be contacted. Since virtually all circuit board test points may be contacted with a few movements, these circuit boards may be tested completely for short-circuits using the method according to the invention.

The table in FIG. 8 shows for a number of circuit boards (boards) the number of circuit board test points (points) to be contacted for a continuity measurement for breaks, the conductor paths (nets), the continuity measurements to be made for breaks (opens test), the measurements which could not be made (opens retests) and their percentage share (retest %).

Measurements which cannot be conducted are measurements of a conductor path section for which its two circuit board test points are not contactable within the number of movements planned.

This calculation is based on the contact layout shown in FIGS. 1 and 2. The maximum number of movements made here is 10.

In the case of all circuit boards, conductor paths must also be retested for breaks, using a finger tester. The proportion lies between 6.8% and 55.7%. Values up to around 30% are very advantageous, since such circuit boards may generally be tested by the method according to the invention almost completely for short-circuits and to a very high percentage for breaks, so that subsequent testing in a finger tester may be carried out very quickly. With higher percentages of e.g. 50% and above (e.g. circuit board 76726A-allOD), the number of movements must be increased or a test set-up with a higher density of test contact elements must be used.

The results given in FIGS. 5A, 5B and 8 show that the method according to the invention is very efficient for a large number of circuit boards, without the need to provide individual adapters for the separate types of circuit board for this purpose.

According to the invention, a test set-up is used which has test contact elements provided at a density of at least 100 per cm². The denser the test contact elements are arranged, the faster a conductor path to be tested can be scanned completely. Therefore, densities of at least 120, 150 or 200 test contact elements per cm² are preferred. Instead of density, the test set-up may also be defined by the grid dimension of adjacent test contact elements, which in the case of the above embodiment is around 0.9 mm. A reduction in the grid dimension to a maximum of 0.8 mm, 0.7 mm, 0.6 mm or 0.5 mm corresponds to an increase in the density of the contact elements and a corresponding reduction in the number of movements to obtain complete contacting of a circuit board to be tested. In the case of the non-componented circuit boards which are currently common, however, a grid dimension of around 0.9 mm is generally sufficient to ensure complete or almost complete contacting of the conductor paths.

The invention has been explained above with the aid of an embodiment in which the testing apparatus has a full grid cassette and a contacting unit. Since the test needles of the contacting unit 6 are all arranged parallel to one another, it is also possible, instead of straight-line wire-like test needles, to use spring contact pins in the contacting unit for contacting the circuit board. Such spring contact pins are for example spiral spring contact elements wound out of wire and with ends arranged centrally relative to the spiral winding. It is sufficient for the spiral winding to extend over only part of the length of the spring contact pin, being preferably located in the central area, so that the straight ends of the spring contact pin may be guided precisely by means of the leader board. A contacting unit equipped with such spring contact pins therefore also contains the function of the full grid cassette, which may then be omitted.

With the present invention, it is no longer necessary to produce a separate adapter for each type of circuit board. On the contrary, with the contacting unit according to the invention, a circuit board may be scanned completely or almost completely in several, but not many, contacting processes. The method according to the invention and the apparatus according to the invention therefore create a universal testing apparatus and a universal testing method, with a throughput for circuit boards to be tested which is somewhat less than for testing with a conventional adapter-based parallel tester, but still significantly higher than with a conventional finger tester. The dwell time of a circuit board to be tested in the parallel tester according to the invention is around 10 to 30 sec. This is 5 to 10 times longer than in a conventional parallel tester but around 10 times faster than in a conventional finger tester.

The method according to the invention is especially efficient in testing for short-circuits since almost all circuit boards may be covered completely with just a few movements (≦10). All circuit board test points which have a diameter or an edge length in the size of the grid spacing I of the test set-up will be contacted in any desired position of the test set-up on the circuit board. This means that all conductor paths which are connected to at least one such circuit board test point are contacted in any desired position of the test set-up. This applies generally to a majority of conductor paths, so that in the first testing position, very many pairs of adjacent conductor paths are already contacted. Short-circuits may thus be detected almost always completely with just a few movements. It may therefore also make sense for certain circuit boards, to use the method according to the invention only for testing for short-circuits, and to test for breaks afterwards using a finger tester.

### LIST OF REFERENCE NUMBERS

1 testing apparatus
2 circuit board
3 body
4 basic grid
5 full grid cassette
6 contacting unit
7 holes
8 contact point
9 spring contact pin
10 test needle
11 leader board
12 column
13 needle guide board
14 positioning board
15 adjusting device
16 adjusting pin
17 positioning hole
18 circuit board locating pin
19 hole
20 positioning hole

1-13. (canceled)

14. A method for testing circuit boards using a testing apparatus, which has a test set-up for contacting circuit board test points of a circuit board to be tested, in which the test set-up has test contact elements in a predetermined regular grid, comprising the steps of:
a) the test set-up is pressed on to the circuit board to be tested in a first testing position relative to the circuit board to be tested, so that several circuit board test points are in contact with at least one test contact element;
b) measurement of several conductor paths for breaks and/or short-circuits by means of continuity measurements;
c) movement of the test set-up relative to the circuit board to be tested into another testing position in which at least one circuit board test point of a conductor path is in contact with at least one test contact element which has not previously been measured fully for breaks and/or short-circuits;
d) measurement of further conductor paths for breaks and/or short-circuits by means of continuity measurements; and
e) repetition of steps c) and d) until at least a majority of conductor paths of the circuit board to be tested have been measured, wherein the test set-up has test contact elements arranged with a density of at least 100 test contact elements per square centimetre.

15. The method according to claim 14, wherein steps c) and d) are repeated until at least 90%, preferably 95% and in particular 99% or 100% of conductor paths have been tested for breaks and/or at least 90%, preferably 95% and in particular 99% or 100% of pairs of adjacent conductor paths have been tested for short-circuits.

16. The method according to claim 14, wherein the circuit board to be tested is subsequently tested by means of a sequential testing apparatus, in particular by means of a finger tester, wherein either potential faults determined by means of the measurements are verified and/or conductor paths not yet contacted are tested.

17. The method according to claim 14, wherein the test contact elements are test needles which are arranged substantially parallel to one another.

18. The method according to claim 14, wherein the test contact elements are arranged in a regular square grid with a maximum grid spacing of 0.90 mm.

19. The method according to claim 14, wherein the test contact elements each comprise a rigid needle for contacting the circuit board test points and a spring contact pin, which are aligned with one another.

20. The method according to claim 14, wherein one or more of the testing positions is checked, by testing at predetermined circuit board test points which should be contacted by at least one pair of test contact elements in the testing position concerned, to establish whether these predetermined circuit board test points are contacted correctly, by checking whether the pair of test contact elements is connected electrically by means of the predetermined circuit board test point.

21. An apparatus for testing of circuit boards comprising:
a test set-up for contacting circuit board test points of a circuit board to be tested, wherein the test set-up has test contact elements in a predetermined regular grid, comprising the following:
a traversing device for moving the test set-up relative to the circuit board to be tested, wherein the traversing device is able to move the test set-up or the circuit board parallel to a plane of the circuit board to be tested in two orthogonal directions by a movement distance at least equal to a distance between two adjacent test contact elements; and
a device for testing conductor paths of the circuit board to be tested for breaks and/or short-circuits, wherein the test contact elements of the test set-up are arranged at a density of at least 100 test contact elements per square centimetre.

22. The apparatus according to claim 21, wherein the traversing device is a piezoelectric adjusting device with two sets of piezoelectric element rods, wherein the two sets of piezoelectric element rods are arranged orthogonal to one another.

23. The apparatus according to claim 21, wherein the traversing device has a motor with reduction gears, which drives an adjusting spindle and/or an eccentric.

24. The apparatus according to claim 21, wherein the test contact elements are test needles arranged substantially parallel to one another.

25. The apparatus according to claim 24, wherein the test needles are held in a contacting unit by means of leader boards.

26. An apparatus for testing of circuit boards comprising:
a test set-up for contacting circuit board test points of a circuit board to be tested, wherein the test set-up has test contact elements in a predetermined regular grid, comprising the following:
a traversing device for moving the test set-up relative to the circuit board to be tested, wherein the traversing device is able to move the test set-up or the circuit board parallel to a plane of the circuit board to be tested in two orthogonal directions by a movement distance at least equal to a distance between two adjacent test contact elements;
a device for testing conductor paths of the circuit board to be tested for breaks and/or short-circuits, wherein the test contact elements of the test set-up are arranged at a density of at least 100 test contact elements per square centimetre; and
a control unit is provided to carry out the method according to claim 14.
